(19) United States
(12) Patent Application Publication
(10) Pub. No.: US 2008/0136797 A1
(43) Pub. Date: Jun. 12, 2008

(54) DISPLAY APPARATUS AND MANUFACTURING METHOD THEREOF

(76) Inventor: Wen-Jyh Sah, Tainan City (TW)

Correspondence Address: BIRCH STEWART KOLASCH & BIRCH, PO BOX 747, FALLS CHURCH, VA, 22040-0747, US

(21) Appl. No.: 11/950,297

(22) Filed: Dec. 4, 2007

(30) Foreign Application Priority Data
Dec. 6, 2006 (TW) 095145333
Nov. 2, 2007 (TW) 096141528

(51) Int. Cl. G06F 3/038; H01L 51/40; H01L 51/05; H01L 29/04

(52) U.S. Cl. 345/204; 438/99; 257/59; 257/40; 257/E51.006; 257/E29.003

(57) ABSTRACT

A display apparatus includes a substrate, an electrode array, a non-crystalline column integrated driving circuit and a non-crystalline row integrated driving circuit. The substrate has a surface. The electrode array is disposed on the surface of the substrate. The non-crystalline column integrated driving circuit is disposed on the surface of the substrate and is electrically connected with the electrode array. The non-crystalline row integrated driving circuit is disposed on the surface of the substrate and is electrically connected with the electrode array. In addition, a manufacturing method of the display apparatus is also disclosed.

### CROSS REFERENCE TO RELATED APPLICATIONS

This Non-provisional application claims priority under 35 U.S.C. §119(a) on Patent Application No(s). 095145333 and 096141528 filed in Taiwan, Republic of China on Dec. 6, 2006 and Nov. 2, 2007, the entire contents of which are hereby incorporated by reference.

### BACKGROUND OF THE INVENTION

1. Field of Invention

The invention relates to a display apparatus and a manufacturing method thereof. More particularly, the invention relates to a display apparatus having a non-crystalline integrated driving circuit and a manufacturing method thereof.

2. Related Art

With the coming of information age, the demands of information communication between human beings and outside have been gradually increased, and the display apparatus capable of broadcasting the information has become one of the indispensable electronic products for the modern life. The display apparatus has been developed from the initial cathode ray tube (CRT) display apparatus to the thinner liquid crystal display (LCD) apparatus, and is widely applied to the communication, information and consumer electronic products.

Generally speaking, a display apparatus 1 shown in FIG. 1 includes a glass substrate 11, a pixel array 12 and a plurality of driving circuit chips 13. The pixel array 12 is disposed on the glass substrate 11 according to the thin film manufacturing technology. The driving circuit chips 13 are manufactured according to the package technology and are then combined with the glass substrate 11 according to the chip-on-glass (COG) manufacturing technology, and are electrically connected with the pixel array 12 to drive the pixel array 12 to generate an image frame.

However, the pixel array 12 is disposed on the glass substrate 11 according to the film manufacturing technology, and then the driving circuit chips 13 are manufactured according to the package technology and are then combined with the glass substrate 11 according to the chip-on-glass (COG) manufacturing technology. Then, the manufacturing processes are complicated. The driving circuit chips 13 may be divided into a scan line driving circuit chip and a data line driving circuit chip, which have to be manufactured according to different manufacturing technology due to different circuit complexity thereof. Thus, the complexity of the manufacturing processes of the display apparatus 1 is increased.

In addition, the size of the substrate 11 has to be configured to provide a space for accommodating the pixel array 12 and the driving circuit chip 13, and a plurality of preserved spaces 111 for the COG manufacturing processes of the driving circuit chip 13 (e.g., the space for the hot pressing head). Thus, the size of the glass substrate 11 cannot be effectively reduced.

Furthermore, as shown in FIG. 2, the thickness D₁ of the driving circuit chip 13 is usually determined according to the chip package design and cannot be easily decreased. Thus, the overall thickness D₀ of the display apparatus 1 cannot be effectively decreased.

Therefore, it is an important subject to provide a display apparatus, which can be manufactured in a simplified manner and has the miniaturized product size, and a manufacturing method thereof.

### SUMMARY OF THE INVENTION

In view of the foregoing, the invention is to provide a display apparatus, which can be manufactured in a simplified manner and has the miniaturized product size, and a manufacturing method thereof.

To achieve the above, the invention discloses a display apparatus including a substrate, an electrode array, a non-crystalline column integrated driving circuit and a non-crystalline row integrated driving circuit. The electrode array is formed on the surface of the substrate. The non-crystalline column integrated driving circuit is formed on the surface of the substrate and electrically connected with the electrode array. The non-crystalline row integrated driving circuit is formed on the surface of the substrate and electrically connected with the electrode array.

To achieve the above, the invention also discloses a manufacturing method of a display apparatus. The method includes the steps of forming a non-crystalline column integrated driving circuit, a non-crystalline row integrated driving circuit and an electrode array on a substrate simultaneously, and disposing an opto-electronic display unit opposite to the electrode array.

As mentioned above, the display apparatus and the manufacturing method thereof according to the invention have the following features. The non-crystalline column integrated driving circuit, the non-crystalline row integrated driving circuit and the electrode array are simultaneously formed on the substrate according to the non-crystalline manufacturing process. Compared with the prior art, in which the pixel array is disposed on the glass substrate according to the thin film manufacturing technology, and the driving circuit chip is manufactured according to the package technology and is then combined with the glass substrate according to the COG manufacturing technology, the manufacturing method of the invention has simplified steps. In addition, the conventional driving circuit chip is replaced with the noncrystalline column integrated driving circuit and the non-crystalline row integrated driving circuit in the invention. Thus, the preserved spaces of the substrate, which are required when the COG manufacturing process is being performed, can be decreased in this invention so that the size of the display apparatus can be reduced and the thickness of the display apparatus can also be relatively decreased.

### BRIEF DESCRIPTION OF THE DRAWINGS

The invention will become more fully understood from the detailed description and accompanying drawings, which are given for illustration only, and thus are not limitative of the present invention, and wherein:

FIG. 1 is a schematic illustration showing a conventional display apparatus;

FIG. 2 is a schematic side view showing the display apparatus of FIG. 1;

FIG. 3 is a schematic illustration showing a display apparatus according to a preferred embodiment of the invention;

FIG. 4 is a schematic illustration showing the display apparatus, which further includes a flexible printed circuit, according to the preferred embodiment of the invention;

FIG. 5A is a schematic illustration showing the display apparatus, which further includes a film and a control chip, according to the preferred embodiment of the invention, wherein the control chip is disposed on the film according to the chip-on-film technology;

FIG. 5B is a schematic illustration showing the display apparatus according to the preferred embodiment of the invention, wherein the control chip is disposed on a surface of a substrate;

FIG. 6 is a schematic illustration showing the display apparatus, which further includes an opposing electrode unit and an opto-electronic display unit, according to the preferred embodiment of the invention;

FIG. 7 is a schematic block diagram showing the display apparatus being an electrophoresis display apparatus according to the preferred embodiment of the invention;

FIG. 8 is a schematic side view showing the display apparatus of FIG. 7; and

FIG. 9 is a schematic flow chart showing a manufacturing method of the display apparatus according to the preferred embodiment of the invention.

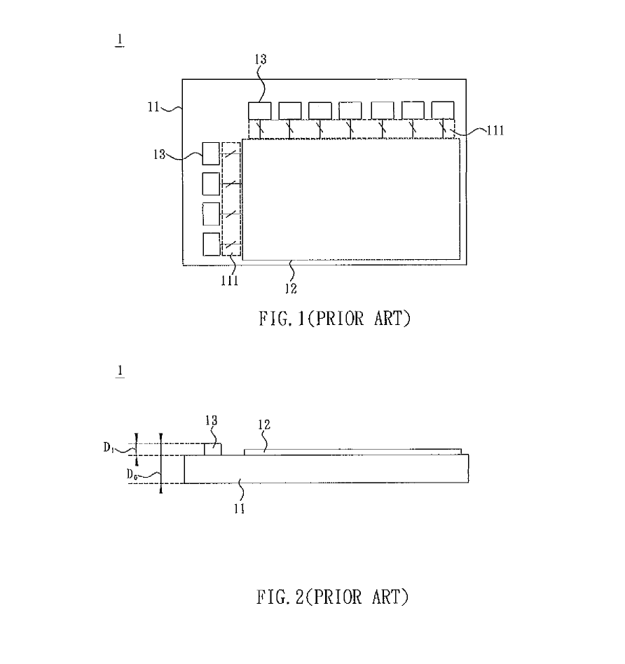

### DETAILED DESCRIPTION OF THE INVENTION

The present invention will be apparent from the following detailed description, which proceeds with reference to the accompanying drawings, wherein the same references relate to the same elements.

Referring to FIG. 3, a display apparatus 2 according to a preferred embodiment of the invention includes a substrate 21, an electrode array 22, a non-crystalline column integrated driving circuit 23 and a non-crystalline row integrated driving circuit 24.

The substrate 21 has a surface 211. The material of the substrate 21 may be modified according to the actual requirement. For example, the substrate 21 may be a glass substrate, a plastic substrate or a stainless steel substrate. In this embodiment, the substrate 21 is a glass substrate.

The electrode array 22, the non-crystalline column integrated driving circuit 23 and the non-crystalline row integrated driving circuit 24 are simultaneously formed on the surface 211 of the substrate 21 according to the non-crystalline manufacturing process. The non-crystalline column integrated driving circuit 23 and the noncrystalline row integrated driving circuit 24 are electrically connected with the electrode array 22 to drive the electrode array 22 to operate. In this embodiment, the non-crystalline manufacturing process may be an amorphous silicon thin film transistor manufacturing process or an organic thin film transistor manufacturing process. Correspondingly, the materials of the electrode array 22, the non-crystalline column integrated driving circuit 23 and the non-crystalline row integrated driving circuit 24 may include amorphous silicon or an organic material. It is to be noted that each of the non-crystalline column integrated driving circuit 23 and the non-crystalline row integrated driving circuit 24 manufactured according to the amorphous silicon thin film transistor manufacturing process has a channel layer of the thin film transistor made of the amorphous silicon.

The electrode array 22 may be designed as an active electrode array according to the actual requirement. The active electrode array includes, without limitation to, a transistor, a thin film transistor or a diode, for example. Of course, the electrode array 22 may also be designed as a passive electrode array, which includes, for example but not limited to, a capacitor.

The non-crystalline column integrated driving circuit 23 is a data line driving circuit, while the non-crystalline row integrated driving circuit 24 is a scan line driving circuit.

As mentioned hereinabove, the electrode array 22, the non-crystalline column integrated driving circuit 23 and the non-crystalline row integrated driving circuit 24 are simultaneously formed on the surface 211 of the substrate 21 according to the non-crystalline manufacturing process. Thus, compared with the prior art, in which the pixel array 12 is disposed on the glass substrate 11 according to the thin film manufacturing technology, and the driving circuit chip 13 is manufactured according to the package technology and is then combined with the glass substrate 11 according to the COG manufacturing technology, the manufacturing method of the invention has simplified steps. In addition, the substrate 21 of the invention may also reduce the preserved spaces 111 of the substrate 11, which are required when the COG manufacturing process is being performed. Therefore, the size of the display apparatus 2 can be reduced.

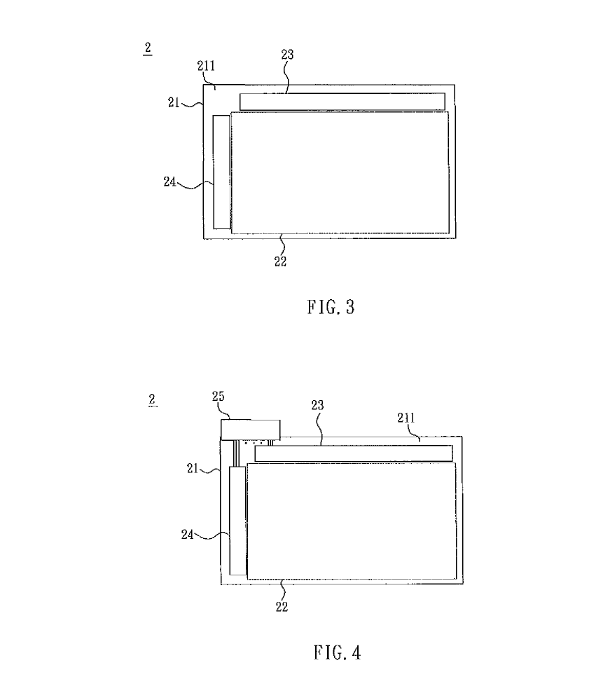

In addition, referring to FIG. 4, the display apparatus 2 may further include a flexible printed circuit (FPC) 25, which is electrically connected with the non-crystalline column integrated driving circuit 23 or the non-crystalline row integrated driving circuit 24. In this embodiment, the FPC 25 is electrically connected with the non-crystalline column integrated driving circuit 23 to transmit image data to the non-crystalline column integrated driving circuit 23. Of course, the FPC 25 may also be simultaneously electrically connected with the non-crystalline column integrated driving circuit 23 and the non-crystalline row integrated driving circuit 24.

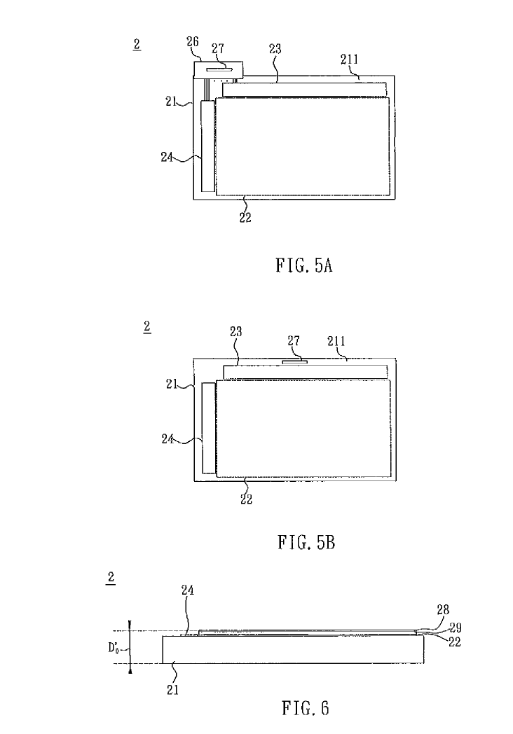

In addition, referring to FIG. 5A, the display apparatus 2 may also include a film 26 and a control chip 27. The film 26 is electrically connected with the non-crystalline column integrated driving circuit 23 or the non-crystalline row integrated driving circuit 24, and the control chip 27 is formed on the film 26 according to the chip-on-film (COF) technology. In this embodiment, the film 26 is electrically connected with the non-crystalline column integrated driving circuit 23 to control the transmission of the image data through the control chip 27. Of course, the film 26 may also be electrically connected with the non-crystalline column integrated driving circuit 23 and the non-crystalline row integrated driving circuit 24. In addition, the control chip 27 may be a time controller or a microcontroller in this embodiment. Because the number of input terminals of each of the non-crystalline column integrated driving circuit 23 or the non-crystalline row integrated driving circuit 24 does not have to be too great, the smaller control chip 27, as shown in FIG. 5B, can be directly disposed on the surface 211 of the substrate 21. Alternatively, a portion of the non-crystalline column integrated driving circuit 23 or the non-crystalline row integrated driving circuit 24 may be disposed on the surface 211 of the substrate 21 in the form of a chip (not shown).

Furthermore, referring to FIG. 6, the display apparatus 2 further includes an opposing electrode unit 28 and an opto-electronic display unit 29.

The opposing electrode unit 28 may be disposed opposite to the electrode array 22. The opposing electrode unit 28 may be an electrode layer or an electrode plate. In addition, the opposing electrode unit 28 has to be a transparent unit, and the material thereof may be indium tin oxide (ITO), aluminum zinc oxide (AZO), indium zinc oxide or cadmium tin oxide.

The opto-electronic display unit 29 is disposed between the opposing electrode unit 28 and the electrode array 22. The opto-electronic display unit 29 may be, without limitation to, a non-volatile opto-electronic display unit. The opto-electronic display unit 29 may be an opto-electronic display element or an opto-electronic display film according to the actual design. In addition, if the display apparatus 2 is an electrophoresis display apparatus, the opto-electronic display unit 29 may include an electrophoresis substance. If the display apparatus 2 is an electrowetting display apparatus, the opto-electronic display unit 29 may include an electrowetting substance. Furthermore, the opto-electronic display unit 29 may also include a cholesterol liquid crystal.

As mentioned hereinabove, the conventional driving circuit chip 13 is replaced with the non-crystalline column integrated driving circuit 23 and the non-crystalline row integrated driving circuit 24 in the display apparatus 2. Thus, the thickness D′₀ of the display apparatus 2 is determined according to the thickness of each of the substrate 21, the opto-electronic display unit 29 and the opposing electrode unit 28, and is not restricted by the thickness D₁ of the driving circuit chip 13. Therefore, the display apparatus 2 is thinner and lighter than the display apparatus 1.

In order to make the invention more comprehensive, the display apparatus of the invention will be described according to one example.

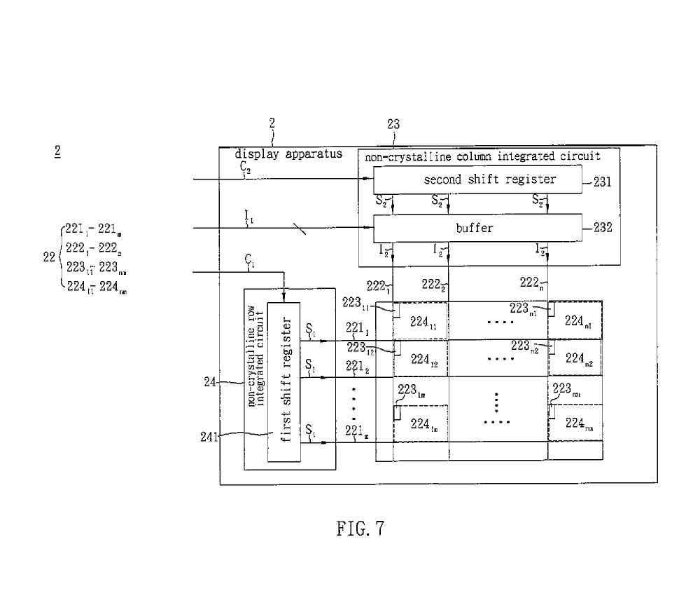

As shown in FIG. 7, the display apparatus 2 is an electrophoresis display apparatus. The electrode array 22 is formed on the substrate 21 according to the amorphous silicon thin film transistor manufacturing process or the organic thin film transistor manufacturing process, and is composed of a plurality of gate scan lines 221₁ to 221ₘ, a plurality of source data lines 222₁ to 222ₙ, a plurality of thin film transistors 223₁₁ to 223ₙₘ and a plurality of pixel electrodes 224₁₁ to 224ₙₘ. The thin film transistors 223₁₁ to 223ₙₘ are respectively electrically connected with the gate scan lines 221₁ to 221ₘ and the source data lines 222₁ to 222ₙ to serve as switches for the pixel electrodes 224₁₁ to 224ₙₘ.

The non-crystalline column integrated driving circuit 23 and the non-crystalline row integrated driving circuit 24 are also formed on the substrate 21 according to the amorphous silicon thin film transistor manufacturing process or the organic thin film transistor manufacturing process. The non-crystalline row integrated driving circuit 24 has a first shift register 241, and the noncrystalline column integrated driving circuit 23 has a second shift register 231 and a buffer 232 electrically connected with the second shift register 231.

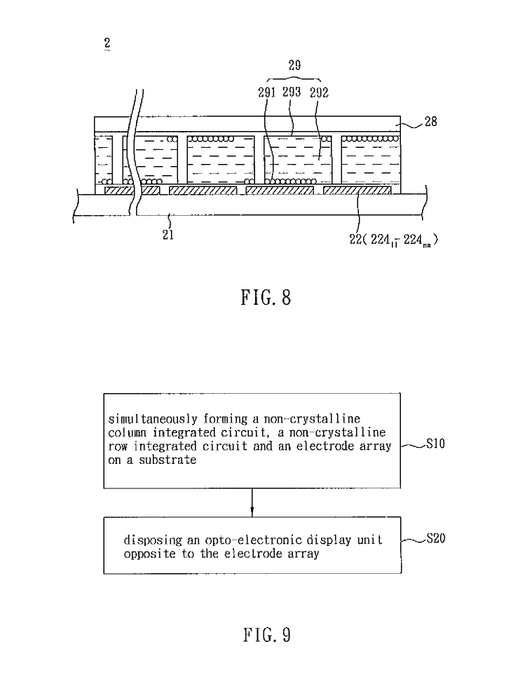

As shown in FIG. 8, a plurality of opto-electronic display units 29 is disposed between the opposing electrode unit 28 and the electrode array 22(pixel electrodes 224₁₁ to 224ₙₘ). The opto-electronic display unit 29 has an electrophoresis substance, which may have a plurality of pigment particles 291 and a dielectric solvent 292. The pigment particles 291 are distributed over the dielectric solvent 292. In this embodiment, the electrophoresis substance (the pigment particles 291 and the dielectric solvent 292) are accommodated within a micro-cup structure 293, and the opto-electronic display unit 29 has, for example but not limited to, a plurality of micro-cup structures 293. Of course, the electrophoresis substance may also be gathered in a micro-capsule structure (not shown). In addition, the material of the opposing electrode unit 28 may be ITO, AZO, indium zinc oxide or cadmium tin oxide.

As shown in FIGS. 7 and 8, when the display apparatus 2 displays the frame, the first shift register 241 operates at the frequency of the gate clock C₁, and sequentially generates a first pulse signal S₁ on the gate scan lines 221₁ to 221ₘ to turn on the thin film transistors 223₁₁ to 223ₙₘ corresponding to the gate scan lines 221₁ to 221ₘ.

The second shift register 231 operates at the frequency of the source clock C₂, and sequentially generates and outputs a second pulse signal S₂ to the buffer 232. The buffer 232 converts sequence image data I₁ into parallel image data I₂ according to the second pulse signal S₂ so as to transmit the parallel image data I₂ to the corresponding thin film transistors 223₁₁ to 223ₙₘ through the source data lines 222₁ to 222ₙ, and thus to control the voltage difference between the opposing electrode unit 28 and the electrode array 22. The pigment particles 291 are forced by the voltage difference to represent the color of the pigment particles 291 or the dielectric solvent 292 so that the micro-cup structure 293 can display different colors.

It is to be noted that the parallel image data represents that the image data, which is transmitted through the source data lines 222₁ to 222ₙ, is correct data during a certain time interval. In other words, the source data lines need not to output the correct image data simultaneously, but only has to sequentially output the image data for a period of time.

Referring to FIG. 9, a manufacturing method of the display apparatus according to the preferred embodiment of the invention includes steps S10 to S20.

In step S10, a non-crystalline column integrated driving circuit, a non-crystalline row integrated driving circuit and an electrode array are simultaneously formed on a substrate. In step S20, an opto-electronic display unit and the electrode array are disposed opposite to each other. In this embodiment, the manufacturing method of the display apparatus has been described in the display apparatus 2 according to the preferred embodiment of the invention (see FIGS. 3 to 8), so detailed descriptions thereof will be omitted.

In summary, the display apparatus and the manufacturing method thereof according to the invention have the following features. The non-crystalline column integrated driving circuit, the non-crystalline row integrated driving circuit and the electrode array are simultaneously formed on the substrate according to the non-crystalline manufacturing process. Compared with the prior art, in which the pixel array is disposed on the glass substrate according to the thin film manufacturing technology, and the driving circuit chip is manufactured according to the package technology and is then combined with the glass substrate according to the COG manufacturing technology, the manufacturing method of the invention has simplified steps. In addition, the conventional driving circuit chip is replaced with the non-crystalline column integrated driving circuit and the non-crystalline row integrated driving circuit in the invention. Thus, the preserved spaces of the substrate, which are required when the COG manufacturing process is being performed, can be decreased in this invention so that the size of the display apparatus can be reduced and the thickness of the display apparatus can also be relatively decreased.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A display apparatus, comprising:
a substrate having a surface;
an electrode array formed on the surface of the substrate;
a non-crystalline column integrated driving circuit formed on the surface of the substrate and electrically connected with the electrode array; and
a non-crystalline row integrated driving circuit formed on the surface of the substrate and electrically connected with the electrode array.

2. The display apparatus according to claim 1, wherein the non-crystalline row integrated driving circuit has a first shift register.

3. The display apparatus according to claim 2, wherein the first shift register is for sequentially generating a first pulse signal.

4. The display apparatus according to claim 1, wherein the non-crystalline column integrated driving circuit has a second shift register.

5. The display apparatus according to claim 4, wherein the second shift register is for sequentially generating a second pulse signal.

6. The display apparatus according to claim 4, wherein the noncrystalline column integrated driving circuit further has a buffer electrically connected with the second shift register for converting serial data into parallel data for output according to the second pulse signal.

7. The display apparatus according to claim 1, wherein the substrate is a glass substrate, a plastic substrate or a stainless substrate.

8. The display apparatus according to claim 1, further comprising a flexible printed circuit electrically connected with the non-crystalline column integrated driving circuit or the non-crystalline row integrated driving circuit.

9. The display apparatus according to claim 1, further comprising:
a film electrically connected with the non-crystalline column integrated driving circuit or the non-crystalline row integrated driving circuit; and
a control chip disposed on the film.

10. The display apparatus according to claim 1, wherein the material of the electrode array comprises amorphous silicon or an organic material.

11. The display apparatus according to claim 1, wherein the material of the non-crystalline column integrated driving circuit or the non-crystalline row integrated driving circuit comprises amorphous silicon or an organic material.

12. The display apparatus according to claim 1, further comprising:
a counter electrode unit disposed opposite to the electrode array; and
an opto-electronic display unit disposed between the counter electrode unit and the electrode array.

13. The display apparatus according to claim 12, wherein the material of the counter electrode unit comprises indium tin oxide (ITO), aluminum zinc oxide (AZO), indium zinc oxide or cadmium tin oxide.

14. The display apparatus according to claim 12, wherein the opto-electronic display unit comprises an electrophoresis substance, an electrowetting substance or a cholesterol liquid crystal.

15. The display apparatus according to claim 14, wherein the electrophoresis substance comprises a plurality of pigment particles and a dielectric solvent, and the pigment particles are distributed over the dielectric solvent.

16. The display apparatus according to claim 14, wherein the opto-electronic display unit further comprises a plurality of micro-capsules, and the electrophoresis substance is accommodated within the micro-capsules.

17. The display apparatus according to claim 14, wherein the opto-electronic display unit further comprises a plurality of micro-cup structures, and the electrophoresis substance is accommodated within the micro-cup structures.

18. The display apparatus according to claim 1, wherein the electrode array is an active electrode array.

19. The display apparatus according to claim 18, wherein the active electrode array comprises a thin film transistor (TFT).

20. A manufacturing method of a display apparatus, the method comprising the steps of:
forming a non-crystalline column integrated driving circuit, a non-crystalline row integrated driving circuit and an electrode array on a substrate simultaneously; and
disposing an opto-electronic display unit opposite to the electrode array.

21. The method according to claim 20, wherein the non-crystalline column integrated driving circuit and the non-crystalline row integrated driving circuit are formed on the substrate by an amorphous silicon thin film transistor manufacturing process or an organic thin film transistor manufacturing process.

22. The method according to claim 20, wherein the electrode array is formed on the substrate by an amorphous silicon thin film transistor manufacturing process or an organic thin film transistor manufacturing process.

23. The method according to claim 20, further comprising the step of disposing a counter electrode unit opposite to the electrode array, wherein the opto-electronic display unit is disposed between the counter electrode unit and the electrode array.
